(19) United States
(12) Patent Application Publication
(10) Pub. No.: US 2026/0313841 A1
(43) Pub. Date: Oct. 8, 2026

(54) SYSTEM FOR COOLING A DATA CENTER USING EVAPORATION HEAT OF LNG LIQUID GAS

(71) Applicant: Belstar Holdings, LLC, New York, NY (US)

(72) Inventor: Daniel J. YUN, New York, NY (US)

(21) Appl. No.: 19/173,640

(22) Filed: Apr. 8, 2025

(51) Int. Cl. H05K 7/20; F17C 7/04

(52) U.S. Cl. CPC H05K 7/20327; F17C 7/04; H05K 7/20827; F17C 2221/033; F17C 2227/0355; F17C 2270/05

(57) ABSTRACT

The present disclosure provides, inter alia, a refrigeration system for a data center using evaporation heat of liquefied natural gas (LNG). The system includes a first main vaporizer configured to vaporize LNG, a first refrigerant storage tank for storing a first refrigerant, a first refrigerant supply pipe for transferring the first refrigerant from the first refrigerant storage tank to the first main vaporizer, a first refrigerant recovery pipe for recovering the first refrigerant cooled by the first main vaporizer to the first refrigerant storage tank, a plurality of first unit coolers installed in the first refrigerant supply pipe for cooling the data center, a first water-cooled refrigerator for cooling the first refrigerant, and a first cooling water circulation unit including a first cooling water circulation pipe for supplying cooling water to the first water-cooled refrigerator and a residual gas vaporizer.

### FIELD OF INVENTION

The present invention relates to a data center cooling system and an environmental test chamber using a liquefied gas vaporizing heat using cold heat generated by vaporizing a liquefied gas stored in an LNG liquefied gas storage tank.

### BACKGROUND OF THE INVENTION

Data centers are facilities that house computer systems and associated components, such as telecommunications and storage systems. These facilities require significant cooling to maintain optimal operating temperatures for the equipment. Traditional cooling methods for data centers often rely on energy-intensive refrigeration cycles, which can be costly and have environmental impacts.

Liquefied natural gas (LNG) is natural gas that has been cooled to a liquid state for ease of storage or transport. The process of returning LNG to a gaseous state, known as regasification, requires the addition of heat. This regasification process presents an opportunity to utilize the cold energy stored in LNG for cooling applications.

The use of LNG cold energy for refrigeration purposes has been explored in various industries. However, the application of this technology to data center cooling presents both opportunities and challenges. The low temperature of LNG makes it a potentially efficient cooling medium, but integrating it into existing data center infrastructure requires careful engineering considerations.

Refrigeration systems that can effectively harness the cold energy from LNG vaporization while meeting the specific cooling needs of data centers are an area of interest. Such systems may offer benefits in terms of energy efficiency and reduced operating costs compared to conventional cooling methods. However, they also introduce complexities related to LNG handling, safety considerations, and system design.

As data centers continue to grow in size and number to support increasing digital demands, finding more efficient and sustainable cooling solutions remains an ongoing focus in the industry. Exploring alternative cooling technologies, including those that leverage industrial byproducts or waste streams, is part of broader efforts to improve data center energy efficiency and reduce environmental impact. The present disclosure is directed to meeting these and other needs.

### SUMMARY OF THE INVENTION

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

According to an aspect of the present disclosure, a refrigerating system for a data center using evaporation heat of liquid natural gas (LNG) is provided. The system includes a first main vaporizer configured to vaporize an LNG liquefied gas. A residual gas vaporizer is provided to vaporize the LNG liquefied gas passing through the first main vaporizer. The system includes a first refrigerant storage tank in which a first refrigerant is stored and a first refrigerant supply pipe for transferring and supplying the first refrigerant from the first refrigerant storage tank to the first main vaporizer. A first refrigerant recovery pipe is provided for recovering the first refrigerant cooled by the first main vaporizer to the first refrigerant storage tank. The system includes a plurality of first unit coolers installed in the first refrigerant supply pipe as a load of the first refrigerant for cooling the inside of the data center. A first refrigerant circulation pipe is provided to supply and recover the first refrigerant stored in the first refrigerant storage tank. The system includes a first water-cooled refrigerator for receiving the first refrigerant stored in the first refrigerant storage tank, cooling the first refrigerant, and then transferring the cooled refrigerant to the first refrigerant storage tank. A first cooling water circulation unit includes a first cooling water circulation pipe for supplying cooling water used as a condensation heat source for the first water-cooled refrigerator to the residual gas vaporizer to vaporize the LNG liquefied gas and recovering the cooling water cooled by the residual gas vaporizer to the first water-cooled refrigerator.

According to other aspects of the present disclosure, the system may include one or more of the following features. The system may include a second main vaporizer provided between the first main vaporizer and the residual gas vaporizer for vaporizing the LNG liquefied gas. The system may include a second refrigerant storage tank for storing a second refrigerant, and a second refrigerant supply pipe for transferring and supplying the second refrigerant from the second refrigerant storage tank to the second main vaporizer. A second refrigerant recovery pipe may be provided for recovering the second refrigerant cooled by the second main vaporizer to the second refrigerant storage tank. The system may include a plurality of second unit coolers installed in the second refrigerant supply pipe as a load of the second refrigerant for cooling the inside of the data center. A second refrigerant circulation pipe may be provided to supply and recover the second refrigerant stored in the second refrigerant storage tank. The system may include a second water-cooled refrigerator for receiving the second refrigerant stored in the second refrigerant storage tank, cooling the second refrigerant, and then transferring the cooled second refrigerant to the second refrigerant storage tank. A second cooling water circulation unit may include a second cooling water circulation pipe for supplying cooling water used as a condensation heat source for the second water-cooled refrigerator to the residual gas vaporizer to vaporize the LNG liquefied gas and recovering the cooling water cooled by the residual gas vaporizer to the second water-cooled refrigerator.

The system may include a cooling water storage tank provided with a low temperature cooling tank in which cooling water cooled by the residual gas vaporizer is stored and a high temperature cooling tank in which cooling water supplied to the residual gas vaporizer is stored. A cooling tower may be provided for cooling the cooling water in the high temperature cooling tank and returning the cooling water to the low temperature cooling tank. The first refrigerant may be R22 and the second refrigerant may be NH3. The first unit coolers may be configured to provide cooling for temperatures ranging from about −60° C. to −25° C. The second unit coolers may be configured to provide cooling for temperatures ranging from about 0° C. to 25° C.

According to some aspects, the present disclosure provides a refrigeration system for a data center using evaporation heat of liquefied natural gas (LNG), comprising: a first main vaporizer configured to vaporize LNG; a first refrigerant storage tank for storing a first refrigerant; a first refrigerant supply pipe for transferring the first refrigerant from the first refrigerant storage tank to the first main vaporizer; a first refrigerant recovery pipe for recovering the first refrigerant cooled by the first main vaporizer to the first refrigerant storage tank; a plurality of first unit coolers installed in the first refrigerant supply pipe for cooling the data center; a first water-cooled refrigerator for cooling the first refrigerant; and a first cooling water circulation unit including a first cooling water circulation pipe for supplying cooling water to the first water-cooled refrigerator and a residual gas vaporizer.

In some embodiments, the refrigeration system further comprising: a second main vaporizer configured to vaporize LNG passing through the first main vaporizer; a second refrigerant storage tank for storing a second refrigerant; a second refrigerant supply pipe for transferring the second refrigerant from the second refrigerant storage tank to the second main vaporizer; and a second refrigerant recovery pipe for recovering the second refrigerant cooled by the second main vaporizer to the second refrigerant storage tank.

In some embodiments, the refrigeration system further comprises a plurality of second unit coolers installed in the second refrigerant supply pipe for cooling the data center. In some embodiments, the refrigeration system further comprises a second water-cooled refrigerator for cooling the second refrigerant. In some embodiments, the refrigeration system further comprises a second cooling water circulation unit including a second cooling water circulation pipe for supplying cooling water to the second water-cooled refrigerator and the residual gas vaporizer.

In some embodiments, the refrigeration system further comprising a cooling water storage tank including a low temperature cooling tank for storing cooling water cooled by the residual gas vaporizer and a high temperature cooling tank for storing cooling water supplied to the residual gas vaporizer. In some embodiments, the refrigeration system further comprising a cooling tower configured to cool the cooling water in the high temperature cooling tank and return the cooled water to the low temperature cooling tank.

According to some aspects, the present disclosure provides a method of cooling a data center using evaporation heat of liquefied natural gas (LNG), comprising: vaporizing LNG in a first main vaporizer; circulating a first refrigerant between a first refrigerant storage tank and the first main vaporizer; cooling the data center using a plurality of first unit coolers installed in a first refrigerant supply pipe; cooling the first refrigerant using a first water-cooled refrigerator; and circulating cooling water between the first water-cooled refrigerator and a residual gas vaporizer.

In some embodiments, the cooling methods disclosed herein further comprise vaporizing LNG in a second main vaporizer after the first main vaporizer; and circulating a second refrigerant between a second refrigerant storage tank and the second main vaporizer. In some embodiments, the cooling methods disclosed herein further comprise cooling the data center using a plurality of second unit coolers installed in a second refrigerant supply pipe. In some embodiments, the cooling methods disclosed herein further comprise cooling the second refrigerant using a second water-cooled refrigerator. In some embodiments, the cooling methods disclosed herein further comprise circulating cooling water between the second water-cooled refrigerator and the residual gas vaporizer. In some embodiments, the cooling methods disclosed herein further comprise storing cooling water in a cooling water storage tank comprising a low temperature cooling tank and a high temperature cooling tank. In some embodiments, the cooling methods disclosed herein further comprise cooling the cooling water in the high temperature cooling tank using a cooling tower and returning the cooled water to the low temperature cooling tank.

According to some aspects, the present disclosure provides, a data center cooling system, comprising: a liquefied natural gas (LNG) vaporization unit including a first main vaporizer; a first refrigerant circulation system coupled to the first main vaporizer and including a plurality of first unit coolers for cooling the data center; a water-cooled refrigeration unit coupled to the first refrigerant circulation system; and a cooling water circulation system coupled to the water-cooled refrigeration unit and a residual gas vaporizer of the LNG vaporization unit.

In some embodiments, the LNG vaporization unit further includes a second main vaporizer configured to vaporize LNG passing through the first main vaporizer. In some embodiments, the data center cooling system further comprises a second refrigerant circulation system coupled to the second main vaporizer and including a plurality of second unit coolers for cooling the data center. In some embodiments, the water-cooled refrigeration unit comprises a first water-cooled refrigerator coupled to the first refrigerant circulation system and a second water-cooled refrigerator coupled to the second refrigerant circulation system.

In some embodiments, the cooling water circulation system includes a cooling water storage tank comprising a low temperature cooling tank for storing cooling water cooled by the residual gas vaporizer and a high temperature cooling tank for storing cooling water supplied to the residual gas vaporizer. In some embodiments, the data center cooling system further comprises a cooling tower configured to cool the cooling water in the high temperature cooling tank and return the cooled water to the low temperature cooling tank.

The foregoing general description of the illustrative embodiments and the following detailed description thereof are merely exemplary aspects of the teachings of this disclosure and are not restrictive.

### BRIEF DESCRIPTION OF THE DRAWINGS

The following drawings form part of the present specification and are included to further demonstrate certain aspects of the present invention. The invention may be better understood by reference to one or more of these drawings in combination with the detailed description of specific embodiments presented herein.

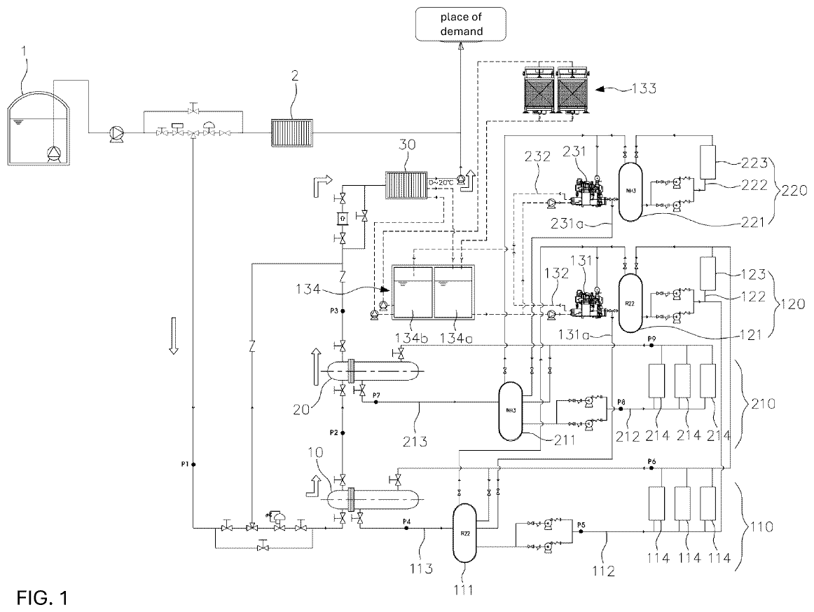

FIG. 1 is a conceptual diagram of a data center cooling system using an evaporated liquefied gas as disclosed herein. Reference is made to the following components:
10: The first main vaporizer
20: the second main vaporizer
30: the residual gas vaporizer
110: the first refrigerant circulation unit
111: the first refrigerant storage tank
112: the first refrigerant supply pipe
113: the first refrigerant recovery pipe
114: A refrigerant circulation pipe
121: a first refrigerant storage tank
122: a first refrigerant circulation pipe
123: a first-second unit cooler
131: a first water-cooled freezer
132: Circulation piping
133: cooling tower
134: cooling water storage tank
210:2-1 refrigerant circulation unit
211:2-1 refrigerant storage tank
212: second refrigerant supply pipe
213: second refrigerant recovery pipe
214: second-1 unit cooler
220:2-2 refrigerant circulation part
221:2-2 refrigerant storage tank
222: second refrigerant circulation pipe
223:2-2 unit cooler
231: second water-cooled freezer
232: second cooling water circulation pipe

### DETAILED DESCRIPTION

### Definitions

The term “about” is used here in conjunction with numeric values to include normal variations in measurements as expected by persons skilled in the art, and is understood have the same meaning as “approximately” and to cover a typical margin of error, such as +5% of the stated value.

Terms such as “a,” “an,” and “the” are not intended to refer to only a singular entity, but include the general class of which a specific example may be used for illustration.

The terms “a,” “an,” and “the” are used interchangeably with the term “at least one.” The phrases “at least one of” and “comprises at least one of” followed by a list refers to any one of the items in the list and any combination of two or more items in the list.

As used here, the term “or” is generally employed in its usual sense including “and/or” unless the content clearly dictates otherwise. The term “and/or” means one or all of the listed elements or a combination y two or more of the listed elements.

As used herein, the term “piping” means not only a passage through which a fluid flows, but also a pump for pumping fluid to be transferred, a valve for opening and closing a passage, and the like. Pumps, valves, and the like can be applied to the piping according to the description of this specification.

### Data Center Cooling System

As disclosed herein, the refrigeration system for data centers using LNG vaporization heat offers numerous benefits that may significantly enhance the efficiency, sustainability, and overall performance of data center cooling operations. This innovative approach leverages the cold energy inherently stored in liquefied natural gas (LNG) during its regasification process, potentially providing a more energy-efficient and environmentally friendly cooling solution compared to conventional methods.

One of the primary advantages of this system may be its ability to utilize what would otherwise be waste energy. During the regasification of LNG, a substantial amount of cold energy is typically released without being harnessed for any practical purpose. By integrating the LNG vaporization process with data center cooling as disclosed herein, this system may effectively capture and repurpose this cold energy, potentially leading to improved overall energy efficiency.

As disclosed herein, a multi-stage vaporization process, incorporating a first main vaporizer, second main vaporizer, and residual gas vaporizer, may allow for optimal extraction of cold energy at different temperature levels. This staged approach may enable the system to cool multiple refrigerant loops operating at different temperature ranges, potentially providing more flexible and precise temperature control within the data center. The ability to maintain different temperature zones may be particularly beneficial in data centers with diverse equipment requirements or those employing hot aisle/cold aisle configurations.

In some cases, the use of two separate refrigerant circulation systems, each coupled to a different main vaporizer, may offer enhanced reliability and redundancy. If one system experiences issues or requires maintenance, the other may continue to provide cooling, potentially reducing the risk of downtime due to cooling system failures. This dual-system approach may also allow for more efficient load balancing and may provide greater flexibility in managing cooling demands across different areas of the data center.

The incorporation of water-cooled refrigeration units in the system may provide additional benefits. These units may serve as a backup cooling mechanism when the LNG supply is interrupted or when cooling demands exceed the capacity provided by the LNG vaporization process alone. This hybrid approach may enhance the system's resilience and adaptability to varying operational conditions and cooling requirements.

From an environmental perspective, the system disclosed herein may offer significant advantages. By utilizing the cold energy from LNG vaporization, which would otherwise be wasted, the system may reduce the overall energy consumption required for data center cooling. This reduction in energy usage may translate to lower greenhouse gas emissions associated with data center operations, potentially helping companies meet sustainability goals and comply with increasingly stringent environmental regulations.

In terms of operational costs, the system disclosed herein may offer potential savings in several areas. By harnessing the cold energy from LNG vaporization, the system may reduce the electricity consumption typically associated with mechanical refrigeration. This reduction in energy usage may lead to lower operating costs over time. Additionally, in regions where LNG terminals are located near data centers, the system may benefit from reduced transportation costs for the cooling medium.

The scalability of the system disclosed herein may be another advantage. As data centers continue to grow in size and power density, cooling requirements are increasing correspondingly. The modular nature of this system, with its multiple vaporizers and refrigerant loops, may allow for easier expansion to meet growing cooling demands. Additional vaporizers or refrigerant circulation systems could potentially be added to the existing infrastructure as needed, providing a flexible solution for data center growth.

In some embodiments, the system disclosed herein may also offer benefits in terms of space efficiency within the data center. By utilizing the cold energy from an external LNG source, the system may reduce the need for large, space-consuming chillers or cooling towers on-site. This could potentially free up valuable real estate within or around the data center facility for other uses, such as additional IT equipment or power distribution systems.

According to some embodiments, disclosed herein, the use of different refrigerants in the two circulation systems (e.g., R22 in the first system and NH3 in the second) may provide opportunities to optimize the cooling performance for different temperature ranges. Each refrigerant has its own thermodynamic properties that may make it more suitable for certain temperature ranges or cooling applications. This tailored approach may contribute to the overall efficiency and effectiveness of the cooling system.

In some embodiments, the refrigerant is one or more of: R-22 (Chlorodifluoromethane); R-134a (1,1,1,2-Tetrafluoroethane); R-410A (Blend of difluoromethane and pentafluoroethane); R-32 (Difluoromethane); R-290 (Propane); R-600a (Isobutane); R-717 (Ammonia); R-744 (Carbon dioxide); R-1234yf (2,3,3,3-Tetrafluoropropene); R-407C (Blend of difluoromethane, pentafluoroethane, and 1,1,1,2-tetrafluoroethane); R-404A (Blend of pentafluoroethane, 1,1,1-trifluoroethane, and 1,1,1,2-tetrafluoroethane); R-507A (Blend of pentafluoroethane and 1,1,1-trifluoroethane); R-152a (1,1-Difluoroethane); R-123 (2,2-Dichloro-1,1,1-trifluoroethane); R-245fa (1,1,1,3,3-Pentafluoropropane); R-1233zd (Trans-1-chloro-3,3,3-trifluoropropene); R-448A (Blend of difluoromethane, pentafluoroethane, 1,1,1,2-tetrafluoroethane, and 2,3,3,3-tetrafluoropropene); R-513A (Blend of 1,1,1,2-tetrafluoroethane and 2,3,3,3-tetrafluoropropene); R-450A (Blend of 1,1,1,2-tetrafluoroethane and 2,3,3,3-tetrafluoropropene); and R-23 (Trifluoromethane).

The inclusion of a cooling water storage and management system disclosed herein, with separate low and high temperature tanks, may offer additional benefits in terms of thermal energy storage and management. This configuration may allow the system to better handle fluctuations in cooling demand and LNG supply, potentially smoothing out operational peaks and troughs. The ability to store cooled water may also provide a buffer against short-term interruptions in LNG supply or unexpected spikes in cooling demand.

From a maintenance perspective, the system disclosed herein may offer additional advantages. The separation of the cooling system into distinct components and loops may allow for easier isolation of individual parts for maintenance or replacement without necessarily shutting down the entire cooling system. This modular approach may contribute to reduced downtime and easier troubleshooting.

In regions where LNG is already being regasified for use as a fuel or feedstock, the system disclosed herein may provide an opportunity for co-location of data centers with LNG terminals. Such co-location can offer synergies in terms of energy efficiency and infrastructure utilization, leading to economic benefits for both the data center operators and the LNG terminal operators.

The system disclosed herein may also contribute to load balancing on the electrical grid. By reducing the electrical demand for cooling, especially during peak hours when electricity prices are typically highest, the system may help data center operators manage their energy costs more effectively. In some cases, this could also provide benefits to the broader electrical grid by reducing strain during high-demand periods.

As disclosed herein, the cooling tower included in the system design may provide additional flexibility and resilience. In cases where the LNG supply is interrupted or cooling demand exceeds the capacity provided by the LNG vaporization process, the cooling tower can supplement the cooling capacity. This hybrid approach may ensure that the data center maintains optimal operating temperatures under a wide range of conditions.

The following description sets forth exemplary aspects of the present disclosure. It should be recognized, however, that such description is not intended as a limitation on the scope of the present disclosure. Rather, the description also encompasses combinations and modifications to those exemplary aspects described herein.

The refrigeration system for the data center using LNG vaporization heat may include multiple components arranged to efficiently utilize the cold energy from liquefied natural gas (LNG) vaporization. FIG. 1 illustrates a schematic diagram of the refrigeration system.

In some embodiments, the cooling system using LNG vaporization heat comprises a first main vaporizer 10, a second main vaporizer 20 and a residual gas vaporizer 30 for vaporizing liquefied gas. In some embodiments, the cooling system comprises a second cooling medium circulation unit 210, a second cooling medium circulation unit 220, a second cooling medium circulation unit 220, a second cooling medium circulation unit 220, a second cooling medium circulation unit 110, and/or a second cooling medium circulation unit 120.

In some embodiments, a first main vaporizer 10 is supplied with a liquefied gas in liquid state (about −130° C.: P1) from the LNG-based eluent liquefied gas storage tank 1 and flows through the first main vaporizer 10 at about −70° C. In some embodiments, the liquefied gas (having been heated) flows to the second main vaporizer 20 and/or to the residual gas vaporizer 30 through the second main vaporizer 20 and is heated to about −5° C. In some embodiments, vaporized gas is finally supplied to the customer (city gas piping, etc.) as vaporized gas in the gaseous state at about 0 to 20° C. through the residual gas vaporizer 30.

In some embodiments, a first refrigerant circulation unit 110 is provided to raise the temperature of the eluent liquefied gas passing through the first main vaporizer 10 to vaporize. In some embodiments, the first refrigerant circulation unit 110 includes a first refrigerant storage tank 111, a first refrigerant supply pipe 112, a first refrigerant recovery pipe 113, and one or more of first unit coolers 114.

In some embodiments, the first refrigerant storage tank 111 stores the first refrigerant. In some embodiments, R22 is used as the first refrigerant.

In some embodiments, a first refrigerant supply pipe 112 and a first refrigerant return pipe 113 are provided between the first refrigerant storage tank 111 and the first main vaporizer 10 for circulating the first refrigerant.

In some embodiments, the first refrigerant supply pipe 112 transports and supplies the first refrigerant from the first refrigerant storage tank 111 to the first main vaporizer 10 to raise the temperature of the liquefied gas passing through the first main vaporizer 10. In some embodiments, the first refrigerant recovery pipe 113 recovers the first refrigerant cooled by the heat of vaporization of the liquefied gas in the first main vaporizer 10 to the first refrigerant storage tank 111.

In some embodiments, the first refrigerant supply pipe 112 is provided with a plurality of first-type unit coolers 114 as a load of the first refrigerant for cooling the inside of the data center.

In some embodiments, the temperature of the first refrigerant immediately before entering the first-type unit cooler 114 is about −75° C. (P5), the temperature of the first refrigerant passing through the first-type unit cooler 114 is about −65° C. (P6), and the temperature of the first refrigerant passing through the first main vaporizer (10) is about −75° C. (P4).

In some embodiments, the second refrigerant circulation unit 210 is provided to raise the temperature of the eluent liquefied gas passing through the second main vaporizer 20 to vaporize. In some embodiments, the second refrigerant circulation unit 210 includes a second refrigerant storage tank 211, a second refrigerant supply pipe 212, a second refrigerant recovery pipe 213, and one or more of second unit coolers 214.

In some embodiments, the second refrigerant storage tank 211 stores a second refrigerant. In some embodiments, NH3 is used as the second refrigerant.

In some embodiments, a second refrigerant supply pipe 212 and a second refrigerant return pipe 213 are provided between the second refrigerant storage tank 211 and the second main vaporizer 20 for circulating the second refrigerant.

In some embodiments, the second refrigerant supply pipe 212 feeds the second refrigerant from the second refrigerant storage tank 211 to the second main vaporizer 10 in order to raise the temperature of the liquefied gas passing through the second main vaporizer 20.

In some embodiments, the second refrigerant recovery pipe 213 recovers the second refrigerant cooled by the heat of vaporization of the liquefied gas in the second main vaporizer 20 to the second refrigerant storage tank 211.

In some embodiments, the second refrigerant supply pipe 212 is provided with one or more of second unit coolers 214 as a load of the second refrigerant for cooling the inside of the data center.

In some embodiments, the temperature of the second refrigerant immediately before entering the second unit cooler 214 is about −10° C. (P8), and the temperature of the second refrigerant passing through the second unit cooler 214 is about −5° C. (P9), and the temperature of the second refrigerant passing through the second main vaporizer 20 is about −10° C. (P7).

In some embodiments, when the interior of the data center is cooled by the first refrigerant circulation part 110 and the second refrigerant circulation part 210, when there is no LNG supplied to the customer (such as holiday, holiday, emergency repair, etc.), that is, when the eluent liquefied gas is not supplied to the first main vaporizer (10, 20, 30), the inside of the data center is not be cooled.

In order keep cooling during a lack of supply of LNG, in some embodiments, a first refrigerant circulation unit 120 and a second refrigerant circulation unit 220 are provided.

In some embodiments, the second refrigerant circulation unit 120 includes a first refrigerant storage tank 121, a first refrigerant circulation pipe 122, and a first and/or second unit coolers 123. In some embodiments, the first refrigerant is stored in the first refrigerant storage tank 121. That is, the refrigerant stored in the first refrigerant storage tank 121 and the refrigerant stored in the refrigerant storage tank 111 are of the same kind. In some embodiments, the first refrigerant circulation pipe 122 is provided for supplying and recovering the first refrigerant stored in the first refrigerant storage tank 121 and the first refrigerant circulation pipe 122 is provided for cooling the inside of the data center. In some embodiments, a first-second unit cooler 123 is provided as a load of the first coolant.

In some embodiments, a first cooling water circulation unit is provided to cool the first refrigerant used as the refrigerant of the first-second refrigerant circulation unit 120. In some embodiments, the first cooling water circulation unit includes a first water-cooling type refrigerator 131, a first cooling water circulation pipe 132, a cooling tower 133, and a cooling water storage tank 134.

In some embodiments, the first water-cooled refrigerator 131 is supplied with the first refrigerant stored in the first refrigerant storage tank 121, cooled and then transferred to the first refrigerant storage tank 121. In some embodiments, the first water-cooled refrigerator 131 performs the compression and condensation processes on the first refrigerant, and uses cooling water as a condensation heat source. That is, the first water-cooled refrigerator 131 is required to continuously supply cooling water for compressing and condensing the refrigerant, particularly for condensing.

In some embodiments, the first cooling water circulation pipe 132 supplies the cooling water used as the condensation heat source of the first water-cooling type refrigerator 131 to the residual gas vaporizer 30 so that the cooling water evaporates the remaining liquefied gas and is cooled, and is provided to recover the cooling water to the first water-cooling type refrigerator 131.

In some embodiments, the cooling tower 133 is connected to the first cooling water circulation pipe 132 so that the cooling water can be cooled even when the eluent liquefied gas is not supplied to the residual gas vaporizer 30. That is, when the eluent liquefied gas is not supplied to the residual gas vaporizer 30, the cooling water used as the condensation heat source of the first water-cooling type refrigerator 131 is cooled by the cooling tower 133 and then conveyed to the first water storage tank.

In some embodiments, in order to cool the cooling water, the first cooling water circulation pipe 132 is provided with a cooling water storage tank 134. In some embodiments, the cooling water storage tank 134 is provided between the residual gas vaporizer 30 and the first water cooling type refrigerator 131 and includes a low temperature cooling tank 134a in which cooling water cooled by the residual gas vaporizer 30 is stored, and a high temperature cooling bath 134b for storing cooling water supplied to the gas vaporizer 30. In some embodiments, the residual gas vaporizer 30 receives the cooling water of the high-temperature cooling bath 134b, and then conveys it to the low-temperature cooling bath 134b. In some embodiments, the cooling tower 133 receives the cooling water of the high-temperature cooling bath 134b and conveys it to the low-temperature cooling bath 134b.

In some embodiments, the second refrigerant circulation unit 220 includes a second refrigerant storage tank 221, a second refrigerant circulation pipe 222, and a second unit cooler 223.

In some embodiments, a second refrigerant is stored in the second refrigerant storage tank 221. That is, the refrigerant stored in the second refrigerant storage tank 221 and the refrigerant stored in the second refrigerant storage tank 211 are of the same kind.

In some embodiments, a second refrigerant circulation pipe 222 is provided to supply and recover the second refrigerant stored in the second refrigerant storage tank 221 and a second refrigerant circulation pipe 222 is provided in the second refrigerant circulation pipe 222 to cool the inside of the data center. In some embodiments, a second unit cooler 223 is provided as a load of the second coolant.

In some embodiments, a second cooling water circulation unit is provided to cool the second refrigerant used as the refrigerant of the second refrigerant circulation unit 220. In some embodiments, the second cooling water circulation unit includes a second water-cooling type refrigerator 231, a second cooling water circulation pipe 232, a cooling tower 133, and a cooling water storage tank 134.

In some embodiments, the second water-cooled freezer 231 receives the second refrigerant stored in the second refrigerant storage tank 221, and after cooling it, transfers it to the second refrigerant storage tank 221.

In some embodiments, the second water-cooled freezer 231 performs the compression and condensation processes on the second refrigerant, and uses cooling water as a condensation heat source. That is, the second water-cooled freezer 231 is required to continuously supply cooling water.

In some embodiments, the second cooling water circulation pipe 232 supplies the cooling water used as the condensation heat source of the second water-cooling type refrigerator 231 to the residual gas vaporizer 30 so that the cooling water evaporates the remaining liquefied gas and is cooled, and is provided to recover the cooling water to the second water-cooled freezer 231.

In some embodiments, the cooling tower 133 is connected to the second cooling water circulation pipe 232 via the cooling water storage tank 134 so that the cooling water can be cooled even when the eluent liquefied gas is not supplied to the residual gas vaporizer 30. That is, when the eluent liquefied gas is not supplied to the residual gas vaporizer 30, the cooling water used as the condensation heat source of the second water-cooled freezer 231 is cooled by the cooling tower 233 and then conveyed to the second water-cooled freezer 231.

In some embodiments, in order to cool the cooling water, the second cooling water circulation pipe 132 is connected to the cooling water storage tank 134. In some embodiments, the structure of the cooling water storage tank 134, the residual gas vaporizer 30 connected thereto and the cooling tower 133 are as disclosed herein.

In some embodiments, the second cooling liquid circulation unit 120, the first cooling liquid circulation unit, the second cooling liquid circulation unit 220, and the second cooling water circulation unit are provided so that about 60 to 70%, and the remaining 30 to 40% of the heat of cooling is generated by the first and second water-cooling type refrigerators 131 and 231.

In some embodiments, the cooling of the cooling water required for the first and second water-cooling type refrigerators 131 and 231 uses the residual gas vaporizer 30, thereby saving energy as much as possible. In some embodiments, when such a hybrid cooling system is used, even when a situation occurs in which the eluent liquefied gas is not supplied to the first main vaporizer, etc., the first and second refrigerant circulation units 120 and 220, it is possible to switch to the emergency cooling system by operating the two water-cooled freezers 131 and 231 and the cooling tower 133. To this end, the first water-cooled refrigerator 131 is supplied with the first refrigerant stored in the first refrigerant storage tank 111, cooled to the first refrigerant storage tank 111, and a refrigerant circulation pipe 131a is provided.

In some embodiments, the second water-cooled refrigerator 231 is supplied with the second refrigerant stored in the second refrigerant storage tank 211 and then cooled to the second refrigerant storage tank 211, and a circulation pipe 231a is provided.

In some embodiments, the unit coolers 114, 123, 214, and 223 are provided inside the data center. The unit coolers normally include a fan unit for introducing air into the unit, exchanging heat with the refrigerant, and blowing air to the ceiling.

In some embodiments, the integration of unit coolers into a data center cooling system may provide additional cooling capacity and flexibility. In the context of the LNG-based refrigeration system described, the unit coolers may be crucial components in efficiently utilizing the cold energy from the vaporizers.

In some embodiments, the unit coolers may be installed along the second refrigerant supply pipe, which circulates the second refrigerant (e.g., NH3 or ammonia) between the second refrigerant storage tank and the second main vaporizer. These coolers may be strategically placed throughout the data center to provide cooling in specific zones or to target particular equipment clusters.

In some embodiments, the unit coolers may be designed to handle temperature ranges from about 0° C. to 25° C., making them suitable for cooling areas of the data center that do not require the extreme low temperatures provided by the first unit coolers. This temperature range may be appropriate for many types of IT equipment, including servers, storage devices, and networking hardware that operate efficiently within this temperature window.

In some embodiments, the integration of unit coolers into the data center may involve several key features:

1. Placement: The unit coolers may be positioned to create cold aisles in a hot aisle/cold aisle configuration. In this arrangement, rows of server racks may be aligned so that their fronts face each other, creating a cold aisle where the cooled air is supplied. The backs of the racks face each other in alternating rows, forming hot aisles where warm exhaust air is collected.

2. Airflow management: To maximize the efficiency of the unit coolers, proper airflow management may be crucial. This may involve the use of physical barriers such as aisle containment systems to separate hot and cold air streams, preventing mixing and improving overall cooling efficiency.

3. Capacity sizing: The cooling capacity of the unit coolers may be carefully calculated based on the heat load of the equipment in their respective zones. This may involve considering factors such as the power consumption of the IT equipment, the desired temperature range, and any redundancy requirements.

4. Control systems: The unit coolers may be integrated into the data center's overall cooling control system. This may allow for dynamic adjustment of cooling output based on real-time temperature and humidity measurements, optimizing energy efficiency and maintaining stable environmental conditions.

5. Redundancy: In some cases, additional unit coolers may be installed to provide N+1 or 2N redundancy, ensuring continuous cooling capability even if one or more units fail or require maintenance.

6. Piping and infrastructure: The integration may require careful planning of the refrigerant piping layout to connect the unit coolers to the second refrigerant supply and return pipes. This may involve considerations such as pipe sizing, insulation, and leak detection systems.

7. Maintenance access: The installation may be designed to allow easy access for maintenance and repairs, potentially including service corridors or removable panels in the data center layout.

8. Monitoring systems: Sensors and monitoring equipment may be installed alongside the unit coolers to track their performance, refrigerant levels, and any potential issues. This data may be integrated into the data center's building management system for comprehensive oversight.

9. Energy recovery: In some implementations, the heat extracted by the unit coolers may be captured and repurposed for other uses, such as office heating or preheating water for other processes, further improving overall energy efficiency.

10. Scalability: The integration may be designed with future expansion in mind, allowing for additional unit coolers to be added as the data center's cooling needs grow.

11. Emergency procedures: The integration may include provisions for emergency cooling in case of a failure in the LNG supply or other critical components. This could involve backup cooling systems or procedures for safely shutting down equipment to prevent overheating.

In some embodiments, the integration of unit coolers into the data center cooling system may also involve considerations related to the specific properties of the second refrigerant. For example, if ammonia (NH3) is used, safety measures such as leak detection systems, proper ventilation, and emergency response procedures may need to be implemented due to ammonia's toxicity and flammability at certain concentrations.

Furthermore, in some embodiments, the integration of unit coolers may allow for more precise zoning of the data center's cooling system. Different areas of the facility may have varying cooling requirements based on the equipment housed there or the level of redundancy needed. The unit coolers may be tailored to meet these specific needs, potentially improving overall energy efficiency by avoiding overcooling in areas that don't require extremely low temperatures.

In some embodiments, the second-stage unit cooler 214 can be used for a C2-class refrigerator (about 0° C.), a C3-class refrigerator (about 5 to 10° C.) and a processing plant air conditioning (about 20 to 25° C.) for the data center.

In some embodiments, the second unit cooler 223 can be used for data center air conditioning (about 20 to 25° C.), a document storage room (about 20 to 25° C.), and/or meeting room (about 20 to 25° C.).

As disclosed herein, the first refrigerant (R-22) and the second refrigerant (NH3) applied to the present embodiments are merely examples, and may be changed to other types of refrigerant. The temperatures of the refrigerants disclosed herein are also just examples.

As shown in FIG. 1, reference numeral 2 denotes a vaporizer 2 for vaporizing the liquefied gas using seawater already installed in a conventional LNG base. When a new LNG base is constructed, the vaporizer 2 may be unnecessary.

All documents cited in this application are hereby incorporated by reference as if recited in full herein. In the event of a conflict between the teachings of this application and those of the incorporated documents, the teachings of this application control.

The embodiments described in this disclosure can be combined in various ways. Any aspect or feature that is described for one embodiment can be incorporated into any other embodiment mentioned in this disclosure. While various novel features of the inventive principles have been shown, described and pointed out as applied to particular embodiments thereof, it should be understood that various omissions and substitutions and changes can be made by those skilled in the art without departing from the spirit of this disclosure. Those skilled in the art will appreciate that the inventive principles can be practiced in other than the described embodiments, which are presented for purposes of illustration and not limitation.

What is claimed is:

1. A refrigeration system for a data center using evaporation heat of liquefied natural gas (LNG), comprising:
a first main vaporizer configured to vaporize LNG;
a first refrigerant storage tank for storing a first refrigerant;
a first refrigerant supply pipe for transferring the first refrigerant from the first refrigerant storage tank to the first main vaporizer;
a first refrigerant recovery pipe for recovering the first refrigerant cooled by the first main vaporizer to the first refrigerant storage tank;
a plurality of first unit coolers installed in the first refrigerant supply pipe for cooling the data center;
a first water-cooled refrigerator for cooling the first refrigerant; and
a first cooling water circulation unit including a first cooling water circulation pipe for supplying cooling water to the first water-cooled refrigerator and a residual gas vaporizer.

2. The refrigeration system of claim 1, further comprising:
a second main vaporizer configured to vaporize LNG passing through the first main vaporizer;
a second refrigerant storage tank for storing a second refrigerant;
a second refrigerant supply pipe for transferring the second refrigerant from the second refrigerant storage tank to the second main vaporizer; and
a second refrigerant recovery pipe for recovering the second refrigerant cooled by the second main vaporizer to the second refrigerant storage tank.

3. The refrigeration system of claim 2, further comprising a plurality of second unit coolers installed in the second refrigerant supply pipe for cooling the data center.

4. The refrigeration system of claim 3, further comprising a second water-cooled refrigerator for cooling the second refrigerant.

5. The refrigeration system of claim 4, further comprising a second cooling water circulation unit including a second cooling water circulation pipe for supplying cooling water to the second water-cooled refrigerator and the residual gas vaporizer.

6. The refrigeration system of claim 5, further comprising a cooling water storage tank including a low temperature cooling tank for storing cooling water cooled by the residual gas vaporizer and a high temperature cooling tank for storing cooling water supplied to the residual gas vaporizer.

7. The refrigeration system of claim 6, further comprising a cooling tower configured to cool the cooling water in the high temperature cooling tank and return the cooled water to the low temperature cooling tank.

8. A method of cooling a data center using evaporation heat of liquefied natural gas (LNG), comprising:
vaporizing LNG in a first main vaporizer;
circulating a first refrigerant between a first refrigerant storage tank and the first main vaporizer;
cooling the data center using a plurality of first unit coolers installed in a first refrigerant supply pipe;
cooling the first refrigerant using a first water-cooled refrigerator; and
circulating cooling water between the first water-cooled refrigerator and a residual gas vaporizer.

9. The method of claim 8, further comprising:
vaporizing LNG in a second main vaporizer after the first main vaporizer; and
circulating a second refrigerant between a second refrigerant storage tank and the second main vaporizer.

10. The method of claim 9, further comprising cooling the data center using a plurality of second unit coolers installed in a second refrigerant supply pipe.

11. The method of claim 10, further comprising cooling the second refrigerant using a second water-cooled refrigerator.

12. The method of claim 11, further comprising circulating cooling water between the second water-cooled refrigerator and the residual gas vaporizer.

13. The method of claim 12, further comprising storing cooling water in a cooling water storage tank comprising a low temperature cooling tank and a high temperature cooling tank.

14. The method of claim 13, further comprising cooling the cooling water in the high temperature cooling tank using a cooling tower and returning the cooled water to the low temperature cooling tank.

15. A data center cooling system, comprising:
a liquefied natural gas (LNG) vaporization unit including a first main vaporizer;
a first refrigerant circulation system coupled to the first main vaporizer and including a plurality of first unit coolers for cooling the data center;
a water-cooled refrigeration unit coupled to the first refrigerant circulation system; and
a cooling water circulation system coupled to the water-cooled refrigeration unit and a residual gas vaporizer of the LNG vaporization unit.

16. The data center cooling system of claim 15, wherein the LNG vaporization unit further includes a second main vaporizer configured to vaporize LNG passing through the first main vaporizer.

17. The data center cooling system of claim 16, further comprising a second refrigerant circulation system coupled to the second main vaporizer and including a plurality of second unit coolers for cooling the data center.

18. The data center cooling system of claim 17, wherein the water-cooled refrigeration unit comprises a first water-cooled refrigerator coupled to the first refrigerant circulation system and a second water-cooled refrigerator coupled to the second refrigerant circulation system.

19. The data center cooling system of claim 18, wherein the cooling water circulation system includes a cooling water storage tank comprising a low temperature cooling tank for storing cooling water cooled by the residual gas vaporizer and a high temperature cooling tank for storing cooling water supplied to the residual gas vaporizer.

20. The data center cooling system of claim 19, further comprising a cooling tower configured to cool the cooling water in the high temperature cooling tank and return the cooled water to the low temperature cooling tank.
